(19) United States
(12) Patent Application Publication
(10) Pub. No.: US 2009/0213888 A1
(43) Pub. Date: Aug. 27, 2009

(54) SEMICONDUCTOR LASER DEVICE AND MANUFACTURING METHOD THEREFOR

(75) Inventor: Tetsuya Yagi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/351,009

(22) Filed: Jan. 9, 2009

(30) Foreign Application Priority Data
Feb. 21, 2008 (JP) 2008-040089

(51) Int. Cl. H01S 5/00; H01L 21/02

(52) U.S. Cl. 372/44.01; 438/33; 257/E21.002

(57) ABSTRACT

A semiconductor laser device includes a semiconductor laser, a dangling bond terminating film a cleaved surface of the semiconductor laser and composed of a lithium film or a beryllium film, and a coating film on the dangling bond terminating film.

### BACKGROUND OF THE INVENTION

1. Field of the Invention

The present invention relates to a semiconductor laser device constructed to prevent degradation of its end faces, and also relates to a method for manufacturing such a semiconductor laser device.

2. Background Art

In semiconductor laser manufacture, an active layer, cladding layers, etc. are formed on a wafer in a wafer fabrication process. The resulting wafer is then cleaved along prescribed planes to produce individual semiconductor laser devices. This cleaving exposes the light emitting end face and the light reflecting end face of each semiconductor laser device to ambient atmosphere.

As a result, native oxide films are formed on these exposed end faces. These native oxide films are removed by plasma processing using an inert gas such as argon. The cleaned light emitting and light reflecting end faces are then each covered with a coating film of alumina (Al₂O₃), etc. to protect the light emitting end face and to enhance the reflectance of the light reflecting end face.

COD (catastrophic optical damage) has been a limiting factor in enhancing the characteristics of semiconductor lasers. COD is instant optical damage to a semiconductor laser due to the produced light energy. COD to the end faces of a semiconductor laser device results in an increase in their temperature, thereby degrading the quality of the end faces over time. In order to avoid this, it has been proposed to treat the coating film on each end face of the semiconductor laser (or resonator), or treat the interface between the end face and the coating film, in various ways. See, e.g., Japanese Laid-Open Patent Publication Nos. 7-283483 (1995), 2002-335053, and 2000-332340 and Published Japanese Translation of PCT Application No. 2005-531154. For example, the above Japanese Laid-Open Patent Publication No. 7-283483 discloses a technique of irradiating the end faces of the resonator (or semiconductor laser) with a hydrogen radical beam within a high vacuum chamber.

The interface states at the interface between each end face of a semiconductor laser (or resonator) and the coating film thereon are considered to be a factor in causing COD to the end face. That is, in operation of the semiconductor laser, light absorption due to such interface states causes COD to the light emitting end face and the light reflecting end face of the laser. It should be noted that these interface states are considered to be the result of the presence of dangling bonds in the light emitting and light reflecting end faces.

However, the above-described general post-cleaving plasma processing (for removing the native oxide film on the light emitting end face, etc. using an inert gas) is not sufficient to ensure the termination of the dangling bonds. If a coating film is formed on the light emitting and light reflecting end faces with the dangling bonds insufficiently terminated, substantial interface states may be formed at the interfaces, resulting in the inability to prevent COD. Further, the method of the above Japanese Laid-Open Patent Publication No. 7-283483 (i.e., irradiating the end faces of the resonator with a hydrogen radical beam within a high vacuum chamber) requires vacuuming that takes a long time to complete, that is, this method is not suited to industrial mass production.

### SUMMARY OF THE INVENTION

The present invention has been devised to solve the above problems. It is, therefore, an object of the present invention to provide a simple method for reducing interface states at the interface between each end face of a semiconductor laser (or resonator) and the coating film thereon to prevent COD.

According to one aspect of the present invention, a semiconductor laser device includes a semiconductor laser, a dangling bond terminating film formed on at least one cleaved surface of the semiconductor laser and composed of a lithium thin film or beryllium thin film, and a coating film formed on the dangling bond terminating film.

According to another aspect of the present invention, a semiconductor laser device includes a semiconductor laser having a cleaved surface terminated with hydrogen, and a coating film formed on the cleaved surface.

According to another aspect of the present invention, a method for manufacturing a semiconductor laser device includes the steps of cleaving a semiconductor laser wafer into a semiconductor laser having an exposed cleaved surface, and forming a dangling bond terminating film on the exposed cleaved surface by sputtering. The dangling bond terminating film being composed of a lithium thin film or beryllium thin film. And the method further includes the step of forming a coating film on the dangling bond terminating film.

According to another aspect of the present invention, a method for manufacturing a semiconductor laser device includes the steps of cleaving a semiconductor laser wafer into a semiconductor laser having an exposed cleaved surface, hydrogen terminating the exposed cleaved surface by hydrogen plasma processing in a sputtering system, and forming a coating film on the hydrogen-terminated cleaved surface after the hydrogen termination step.

Other and further objects, features and advantages of the invention will appear more fully from the following description.

### BRIEF DESCRIPTION OF THE DRAWINGS

FIG. 1 is cross-sectional view of the semiconductor laser device according to the present invention;

FIG. 2 is a flowchart of a method for manufacturing a semiconductor laser device according to the present invention;

FIG. 3 shows the light reflecting end face covered with a lithium thin film; and

FIG. 4 shows the hydrogen terminated light emitting end face (or light reflecting end face).

### DETAILED DESCRIPTION OF THE PREFERRED EMBODIMENTS

### Embodiment

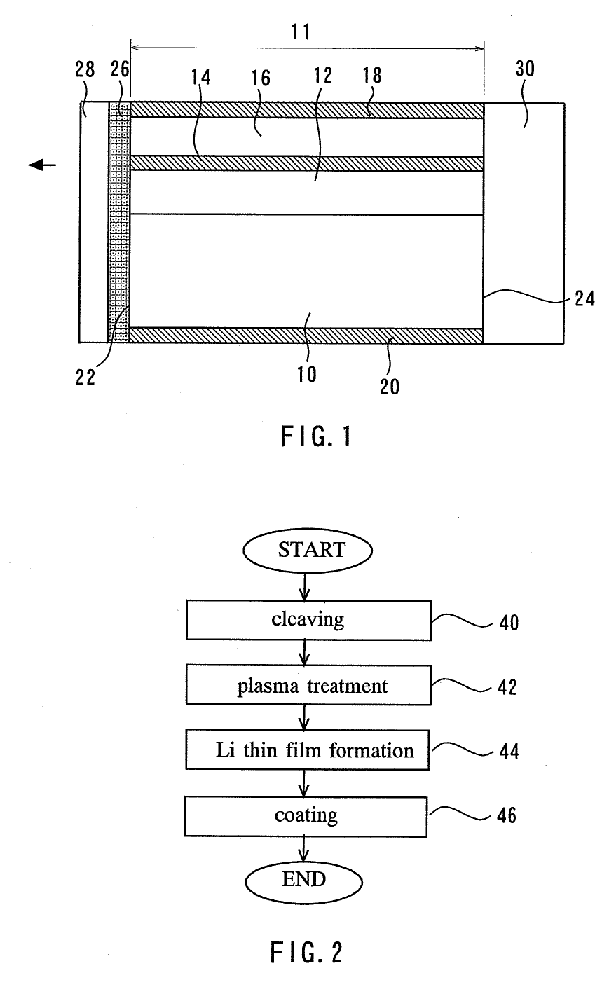

There will now described, with reference to FIG. 1, the configuration of a semiconductor laser device according to a first embodiment of the present invention. This semiconductor laser device includes a semiconductor laser (or resonator) 11 and a lithium thin film and a coating film (described later).

The semiconductor laser 11 constitutes the resonator portion of the semiconductor laser device of the present embodiment, and includes a substrate 10. A first cladding layer 12 is formed on and in contact with the top surface of the substrate 10, and an active layer 14 is formed on and in contact with the first cladding layer 12. In the active layer 14, carriers recombine to emit light. A second cladding layer 16 is formed on and in contact with the active layer 14. Further, an electrode 18 is disposed on and in contact with the second cladding layer 16, and an electrode 20 is disposed on and in contact with the bottom surface of the substrate 10 (i.e., the bottom surface of the semiconductor laser 11).

The semiconductor laser 11 has a light emitting end face 22 for emitting light and a light reflecting end face 24 for reflecting light. These end faces are formed by cleaved surfaces. A lithium thin film 26 is formed on the light emitting end face 22 to a thickness of 10 nm. Further, a low reflecting film 28 of alumina (Al₂O₃) is formed on and in contact with the lithium thin film 26. On the other hand, a high reflecting film 30 is formed on and in contact with the light reflecting end face 24. The low reflecting film 28 and the high reflecting film 30 each have a thickness equal to λ/4*n (where λ is the wavelength of the light and n is the refractive index). These films may have a multilayer structure. According to the present embodiment, the low and high reflecting films 28 and 30 are referred to as “coating films.”

With reference to the flowchart shown in FIG. 2, there will now be described a method for manufacturing a semiconductor laser device according to the present invention. Referring to FIG. 2, at step 40, a wafer with active and cladding layers formed thereon is cleaved into individual semiconductor lasers 11. As a result of this cleaving step, the light emitting end face 22 and the light reflecting end face 24 of each semiconductor laser 11 are exposed to ambient air.

The method then proceeds to step 42 at which the native oxide films formed on the light emitting and light reflecting end faces 22 and 24 are removed by an inert gas plasma, such as a plasma generated from argon. It should be noted that this removal processing may use nitrogen plasma.

The method then proceeds to step 44 at which a lithium thin film 26 is formed on the light emitting end face 22 by sputtering. The chamber of the sputtering system is maintained at an internal pressure of a few tens to a few hundreds of Torr, meaning that the sputtering system need not be adapted to a high vacuum. As a result, this step can be completed in a short time and the semiconductor laser device can be reliably manufactured at low cost. It should be noted that according to the present embodiment, the lithium thin film 26 (formed by sputtering as described above) has a thickness of 10 nm.

The method then proceeds to step 46 at which a low reflecting film 28 is formed on the lithium thin film 26, and a high reflecting film 30 is formed on and in contact with the light reflecting end face 24. More specifically, both the low reflecting film 28 and the high reflecting film 30 are formed by first forming alumina and then forming a high refractive index film or a low refractive index film. That is, these reflecting films may have any configuration that allows them to have the desired refractive index.

When a semiconductor laser device is in operation, light is absorbed by the end portions extending its light emitting end face and light reflecting end face, which may cause COD to these end faces. This light absorption is considered to be caused by interface states formed at the interface between each end face and the coating film thereon due to the presence of dangling bonds in the end face. Such dangling bonds cannot be sufficiently terminated by the post-cleaving plasma processing, which cleans the light emitting and light reflecting end faces with an inert gas plasma or nitrogen plasma. As a result, in the past, these end faces have suffered COD. It will be noted that the light emitting end face is more likely to suffer COD than the light reflecting end face since the former has a higher optical density than the latter, although COD to the light reflecting end face has also been observed in the past.

This problem is solved with the semiconductor laser device and manufacturing method of the present embodiment. Specifically, in the semiconductor laser device of the present embodiment, the dangling bonds in the light emitting end face 22 are terminated with the lithium thin film 26. (Lithium is an active material and hence is suitable for terminating dangling bonds.) Therefore, the interface states at the interface between the light emitting end face 22 and the low reflecting film (or coating film) 28 thereon are reduced, resulting in reduced COD to the end face.

Although the lithium thin film (26) has been described as having a thickness of 10 nm, it may have a thickness within the range of approximately 1-20 nm. The minimum thickness (1 nm) corresponds approximately to two-atomic-layer thickness of lithium; the thickness of the lithium thin film must be equal to or greater than this thickness to ensure the termination of the dangling bonds. The maximum thickness (approximately 20 nm) of the lithium thin film is determined so that the light absorption by the lithium film does not affect the operation of the semiconductor laser device and hence can be ignored (although the thicker the lithium film, the more reliable the termination of the dangling bonds). In-situ observation by XPS (X-ray photoelectron spectroscopy) may be performed to accurately control the thickness of the lithium thin film.

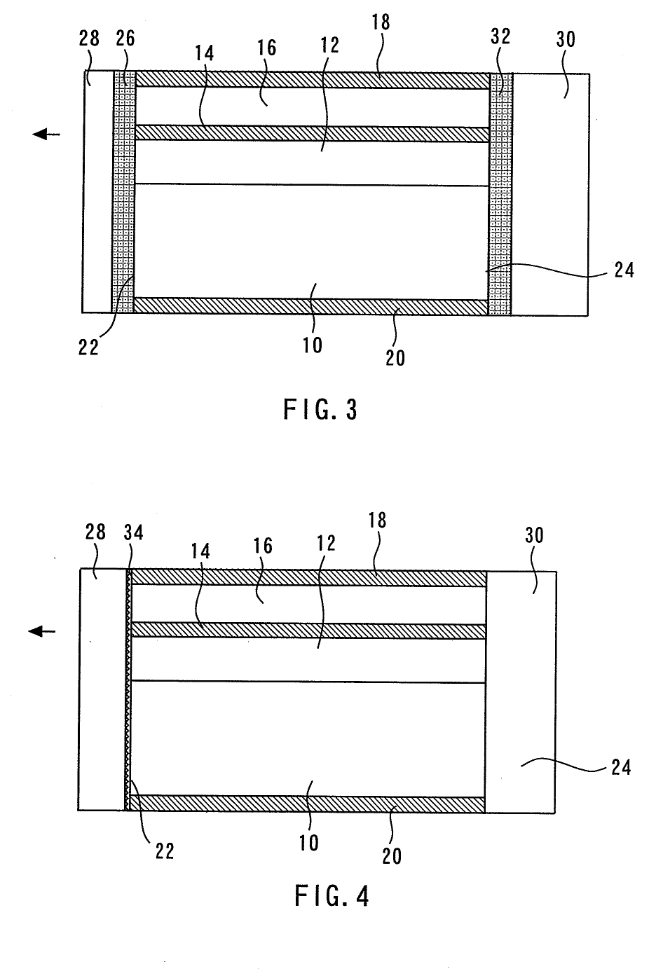

Although in the present embodiment only the light emitting end face 22 is covered with a lithium thin film, it is to be understood that in other embodiments the light reflecting end face 24 may also be covered with a lithium thin film (32), as shown in FIG. 3, to prevent COD to this end face.

Although in the present embodiment the dangling bonds in the light emitting end face are terminated with a lithium thin film, it is to be understood that in other embodiments the dangling bonds in the light emitting end face (or light reflecting end face) may be, for example, hydrogen terminated with a hydrogen termination portion (34), as shown in FIG. 4, with the same effect. This hydrogen termination may be achieved by hydrogen plasma processing performed within the chamber of the sputtering system, thereby eliminating the need to create a high vacuum. Such a hydrogen termination step can be performed immediately upon completion of the plasma processing step (42) shown in FIG. 2, using the same equipment. Further, the use of hydrogen for termination facilitates the manufacture of the semiconductor laser device as compared to the use of lithium, which is a pyrophoric material and hence requires care in handling.

Although in the present embodiment dangling bonds in the light emitting end face are terminated with a lithium thin film to prevent COD to the end face, it is to be understood that in other embodiments other material (or dangling bond terminating films) may be used to terminate these dangling bonds. For example, a beryllium thin film may be substituted for the lithium thin film, with the same effect.

The semiconductor laser 11 of the present embodiment may be made of, but is not limited to, a Group III-V semiconductor such as GaN and InGaAs. Further, the semiconductor laser may have any configuration that enables COD to its light emitting end face or light reflecting end face to be prevented in the manner described above.

Thus the present invention provides a technique of preventing COD to the end faces of a semiconductor laser device and the resulting degradation of their quality.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2008-040089, filed on Feb. 21, 2008 including specification, claims, drawings and summary, on which the Convention priority of the present application is based, are incorporated herein by reference in its entirety.

1. A semiconductor laser device comprising:
a semiconductor laser;
a dangling bond terminating film on at least one cleaved surface of said semiconductor laser and composed of a lithium film or a beryllium film; and
a coating film on said dangling bond terminating film.

2. The semiconductor laser device as claimed in claim 1, wherein said dangling bond terminating film has a thickness in a range from 1 to 20 nm.

3. The semiconductor laser device as claimed in claim 1, wherein said at least one cleaved surface is a light emitting end face.

4. The semiconductor laser device as claimed in claim 1, wherein said at least one cleaved surface is a light emitting end face or a light reflecting end face.

5. A semiconductor laser device comprising:
a semiconductor laser having a cleaved surface terminated with hydrogen; and
a coating film on said cleaved surface.

6. A method for manufacturing a semiconductor laser device, comprising:
cleaving a semiconductor laser wafer into a semiconductor laser having an exposed cleaved surface;
forming a dangling bond terminating film on said exposed cleaved surface by sputtering, said dangling bond terminating film being a lithium film or a beryllium film; and
forming a coating film on said dangling bond terminating film.

7. A method for manufacturing a semiconductor laser device, comprising:
cleaving a semiconductor laser wafer into a semiconductor laser having an exposed cleaved surface;
hydrogen terminating said exposed cleaved surface by hydrogen plasma processing in a sputtering system; and
forming a coating film on said hydrogen-terminated cleaved surface after said hydrogen terminating.
